(19) United States
(12) Patent Application Publication
(10) Pub. No.: US 2019/0189186 A1
(43) Pub. Date: Jun. 20, 2019

(54) SUB-WORD LINE DRIVERS AND RELATED SEMICONDUCTOR MEMORY DEVICES

(71) Applicant: Samsung Electronics Co., Ltd., Suwon-si (KR)

(72) Inventors: Bok-Yeon Won, Namyangju-si (KR); Hyuckjoon Kwon, Yongin-si (KR)

(21) Appl. No.: 16/034,604

(22) Filed: Jul. 13, 2018

(30) Foreign Application Priority Data
Dec. 18, 2017 (KR) 10-2017-0174402

(51) Int. Cl. G11C 11/408; H01L 27/02; H01L 27/108

(52) U.S. Cl. CPC G11C 11/4085; H01L 27/10805; H01L 27/0207

(57) ABSTRACT

Semiconductor memory devices are provided. A semiconductor memory device includes a first keeper transistor that is connected to a first word line. The semiconductor memory device includes a second keeper transistor that is connected to a second word line. The first keeper transistor and the second keeper transistor have a merged channel. In some embodiments, the first keeper transistor and the second keeper transistor are in a sub-word line driver.

### CROSS-REFERENCE TO RELATED APPLICATIONS

This application claims priority under 35 U.S.C. § 119 to Korean Patent Application No. 10-2017-0174402, filed on Dec. 18, 2017, in the Korean Intellectual Property Office, the disclosure of which is hereby incorporated by reference herein in its entirety.

### BACKGROUND

The present disclosure relates to semiconductor memory devices, and, more particularly, relates to sub-word line drivers for driving word lines and semiconductor memory devices including sub-word line drivers.

The capacity and speed of a semiconductor memory device used in various electronic systems are increasing based on user demand for high performance. In particular, a typical example of a volatile memory device may be a dynamic random access memory (DRAM). A memory cell of the DRAM stores data in the form of charges that are charged in a cell capacitor. The DRAM writes or reads data in or from memory cells by using a word line and a bit line. Memory cells connected to a word line may constitute one row and may operate based on a voltage applied to a word line.

As the capacity of the DRAM increases, the number of memory cells connected to one word line may increase, and a distance (or a cell pitch) between word lines may shrink. In the case where a word line voltage is applied to a word line connected with more memory cells, a speed delay issue may occur. To improve the delay of the word line voltage, a technique to divide one word line into a plurality of sub-word lines and drive each sub-word line by using a sub-word line driver SWD may be used.

However, even though the distance (or cell pitch) between word lines shrinks as the degree of integration increases, there is a limitation in reducing the size of a sub-word line driver SWD. If the size of transistors of the sub-word line driver for providing a word line voltage VPP that is a high voltage decreases, the transistors may be degraded due to high-voltage stress.

### SUMMARY

Embodiments of present inventive concepts provide a sub-word line driver with resistance to degradation even though a cell pitch is relatively small, and a semiconductor memory device including the same.

According to some example embodiments, a semiconductor memory device may include a first sub-word line driver that includes a first keeper transistor that is configured to supply a negative voltage to a first word line in response to a driving signal. The semiconductor memory device may include a second sub-word line driver that includes a second keeper transistor that is configured to supply the negative voltage to a second word line in response to the driving signal. The first keeper transistor and the second keeper transistor may jointly include a first active pattern extending in a first direction intersecting the first word line and the second word line and connected with the first word line and the second word line through a first direct contact and a second direct contact, respectively. The first keeper transistor and the second keeper transistor may jointly include a second active pattern protruding from the first active pattern in a second direction intersecting the first direction and connected with a third direct contact that is configured to supply the negative voltage. Moreover, the first keeper transistor and the second keeper transistor may include a gate pattern on a portion of the first active pattern.

According to some example embodiments, a sub-word line driver of a semiconductor memory device may include a substrate that includes a first drain region and a second drain region of a plurality of keeper transistors, and a common source region of the plurality of keeper transistors. The plurality of keeper transistors may be configured to couple a plurality of inactive word lines to a negative voltage. Moreover, the sub-word line driver of the semiconductor memory device may include a common gate electrode of the plurality of keeper transistors. The common source region of the plurality of keeper transistors may be non-collinear with the first drain region and the second drain region of the plurality of keeper transistors.

According to some example embodiments, a semiconductor memory device may include a first keeper transistor that is connected to a first word line, and that is configured to supply a voltage to the first word line in response to a driving signal. Moreover, the semiconductor memory device may include a second keeper transistor that is connected to a second word line, and that is configured to supply the voltage to the second word line in response to the driving signal. The first keeper transistor and the second keeper transistor may have a merged channel.

### BRIEF DESCRIPTION OF THE FIGURES

The above and other objects and features of present inventive concepts will become apparent by describing in detail example embodiments thereof with reference to the accompanying drawings.

FIG. 1 is a block diagram illustrating a core structure of a dynamic random access memory device according to some embodiments of present inventive concepts.

FIG. 2 is a block diagram illustrating adjacent sub-word line drivers according to some embodiments of present inventive concepts.

FIG. 3 is a circuit diagram illustrating a structure of sub-word line drivers illustrated in FIG. 2.

FIG. 4 is a waveform diagram illustrating an operation of a sub-word line driver of FIG. 3.

FIG. 5 is a view illustrating a layout of a merged keeping transistor of FIG. 3.

FIG. 6 is a sectional view of a merged keeping transistor taken along a line A-A′ of FIG. 5.

FIG. 7 is a sectional view of a merged keeping transistor taken along a line B-B′ of FIG. 5.

FIG. 8 is a view schematically illustrating a channel shape of a keeping transistor according to some embodiments of present inventive concepts.

FIG. 9 illustrates a layout of an example of a merged keeping transistor according to some embodiments of present inventive concepts.

FIG. 10 illustrates a layout of an example of a merged keeping transistor according to some embodiments of present inventive concepts.

FIG. 11 illustrates an example layout of keeping transistor stages constituting a sub-word line driver of present inventive concepts.

FIG. 12 is a block diagram illustrating a computing system including a semiconductor memory device according to some embodiments of present inventive concepts.

FIG. 13 is a block diagram illustrating a structure of a three-dimensionally stacked memory chip including a DRAM according to some embodiments of present inventive concepts.

FIG. 14 is a block diagram illustrating a structure of a stacked memory chip including a DRAM according to some embodiments of present inventive concepts.

### DETAILED DESCRIPTION

Hereinafter, present inventive concepts will be described in detail by explaining embodiments of present inventive concepts with reference to the attached drawings. Like reference numerals in the drawings denote like elements, and redundant explanations of like elements may be omitted.

Below, a synchronous DRAM (SDRAM) may be used as an example of a semiconductor device for describing features and functions of present inventive concepts. However, one skilled in the art may easily understand other merits, applications, and performance of present inventive concepts in view of the contents disclosed herein. Present inventive concepts may thus be implemented or applied through other embodiments.

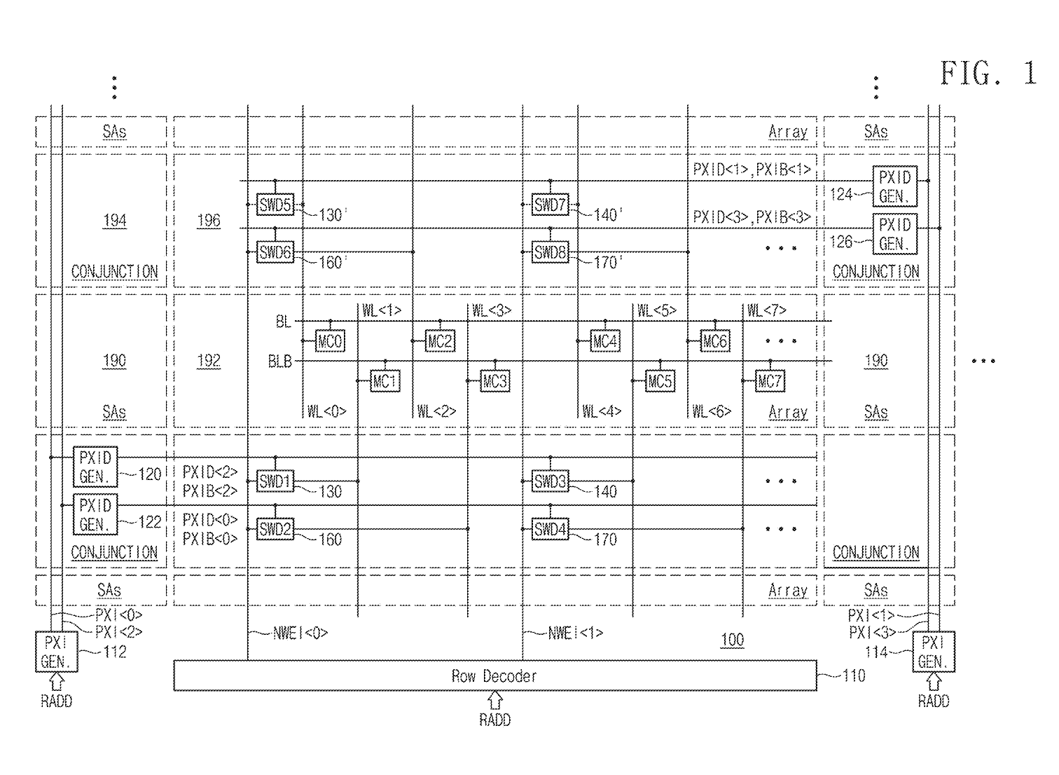

FIG. 1 is a block diagram illustrating a core structure of a dynamic random access memory device (DRAM) according to some embodiments of present inventive concepts. Referring to FIG. 1, a DRAM 100 may include a row decoder 110, pre-decoders (PXI GEN.) 112 and 114, driving voltage generators (PXID GEN.) 120, 122, 124, and 126, sub-word line drivers (SWD) 130, 140, 160, and 170, sense amplifiers (SA) (e.g., SA blocks) 190, a cell array 192, and conjunctions 194. Here, because present inventive concepts relate to a sub-word line driver, a description associated with a column selection structure may be omitted.

The row decoder 110 selects a word line of a memory cell to be accessed, in response to an input row address RADD. The row decoder 110 decodes the input row address RADD to generate word line enable signals NWEI<n> (n being an integer more than “0”) for enabling a corresponding word line. The word line enable signals NWEI<n> of the row decoder 110 may be activated in a write operation mode and a read operation mode associated with selected memory cells. Also, in a self-refresh operation mode, the row decoder 110 may decode a row address RADD generated from an address counter and may enable a corresponding word line.

The pre-decoders 112 and 114 generate pre-decoding signals PXI<0>, PXI<1>, PXI<2>, PXI<3>, etc. in response to the row address RADD. For example, the pre-decoders 112 and 114 may decode lower bits of the row address RADD to generate pre-decoding signals PXI<j> (j being an integer more than “0”) corresponding to a selected word line. The pre-decoding signals PXI<j> are transmitted to the driving voltage generators 120, 122, 124, and 126 within the conjunctions 194 through main word lines.

The driving voltage generators 120, 122, 124, and 126 generate driving signals PXID<i> and PXIB<i> for driving a word line in response to the pre-decoding signals PXI<0>, PXI<1>, PXI<2>, PXI<3>, etc. As the integration and speed of a semiconductor memory device become higher, a level of a high voltage VPP for driving a word line may have an influence on the reliability of the semiconductor memory device. To improve the reliability of the semiconductor memory device, it may be beneficial to decrease the level of the high voltage VPP and to inhibit/prevent a decrease in a high-voltage level due to a leakage current or the like at the same time. Accordingly, the driving voltage generators 120, 122, 124, and 126 include a pull-up driver for the purpose of supplying the high voltage VPP to a selected word line. In general, the pull-up driver is implemented with a PMOS transistor.

The sub-word line drivers 130, 140, 160, and 170 may activate or precharge a selected word line in response to the word line enable signals NWEI<n> and the driving signals PXID<i> and PXIB<i>. In the case where a memory cell MC1 is selected, the word line enable signal NWEI<0> is activated, and the driving signals PXID<2> and PXIB<2> provided from the driving voltage generator 120 are activated. In this case, the sub-word line driver 130 may drive a word line WL<1> with the high voltage VPP being a level of the driving signal PXID<2>. The operation of the sub-word line driver 130 is identically applied to the remaining sub-word line drivers 140, 160, 170, 130′, 140′, 160′, and 170′.

In particular, each of the sub-word line drivers 130, 140, 160, 170, 130′, 140′, 160′, and 170′ includes a respective keeping transistor. The keeping transistors may be NMOS transistors. The sub-word line drivers 130, 140, 160, 170, 130′, 140′, 160′, and 170′ may precharge a deactivated word line with a negative voltage VBB2 through the keeping transistor. For example, the sub-word line driver 130 includes a keeping transistor that is configured to precharge the word line WL<1> with the negative voltage VBB2 in response to the driving signal PXIB<2>. Likewise, the sub-word line driver 140 includes a keeping transistor that is configured to precharge a word line WL<5> with the negative voltage VBB2 in response to the driving signal PXIB<2>.

Two keeping transistors of the adjacent sub-word line drivers 130 and 140, respectively, according to present inventive concepts may be merged to share a gate electrode and to include one common source to which the negative voltage VBB2 is provided. That is, a pattern of a common gate electrode of the adjacent sub-word line drivers 130 and 140 may be provided to form a single channel. For example, with regard to the two keeping transistors, an active pattern may be implemented to form separated drains respectively connected to word lines and to form a common source for supplying the negative voltage VBB2. In particular, a common gate electrode may be formed on the active pattern such that a T-shaped channel connecting the separated drains and the common source is formed. For example, the common gate electrode may be formed in the shape of a square, an octagon, a circle, or an ellipse.

A length of a channel of the keeping transistors may be easily extended by a shape of the common gate pattern of the adjacent keeping transistors and a protrusion shape of the common source of the adjacent keeping transistors. Accordingly, even though the high voltage VPP is applied to a gate of a keeping transistor, the extended channel may allow the keeping transistors to resist degradation. The layout of the keeping transistor will be more fully described with reference to accompanying drawings. The channel structure of the keeping transistor may be identically applied to the adjacent sub-word line drivers 160 and 170, and to the sub-word line drivers 130′, 140′, 160′, and 170′ placed on the upper side of the cell array 192.

The sense amplifier block 190 accesses a memory cell through a bit line pair BL and BLB of a selected column in response to a column address. Also, the sense amplifier block 190 may further include components for storing input data in a selected memory cell. The sense amplifier block 190 may rewrite data stored in a memory cell during a self-refresh mode. The sense amplifier block 190 may be connected with memory cells in an open bit line structure.

The cell array 192 includes a plurality of memory cells that are connected with word lines WL and bit lines BL and are arranged in a row direction and a column direction. Each of the memory cells may include a cell capacitor and an access transistor. In each memory cell, a gate of the access transistor is connected to any one of the word lines WL arranged in the row direction. A first end of the access transistor is connected to a bit line BL or a complementary bit line BLB extending in the column direction. A second end of the access transistor may be connected to the cell capacitor.

The sub-word line drivers SWD of the DRAM 100 according to some embodiments of present inventive concepts may include a merged keeping transistor having an increased channel length. That is, keeping transistors of adjacent sub-word line drivers SWD include an active area for forming a T-shaped channel. Accordingly, even though a cell pitch decreases, a channel length of a keeping transistor of a sub-word line driver may not decrease (and, in some embodiments, may not increase). This may mean that a sub-word line driver with a driving capacity of high reliability is implemented.

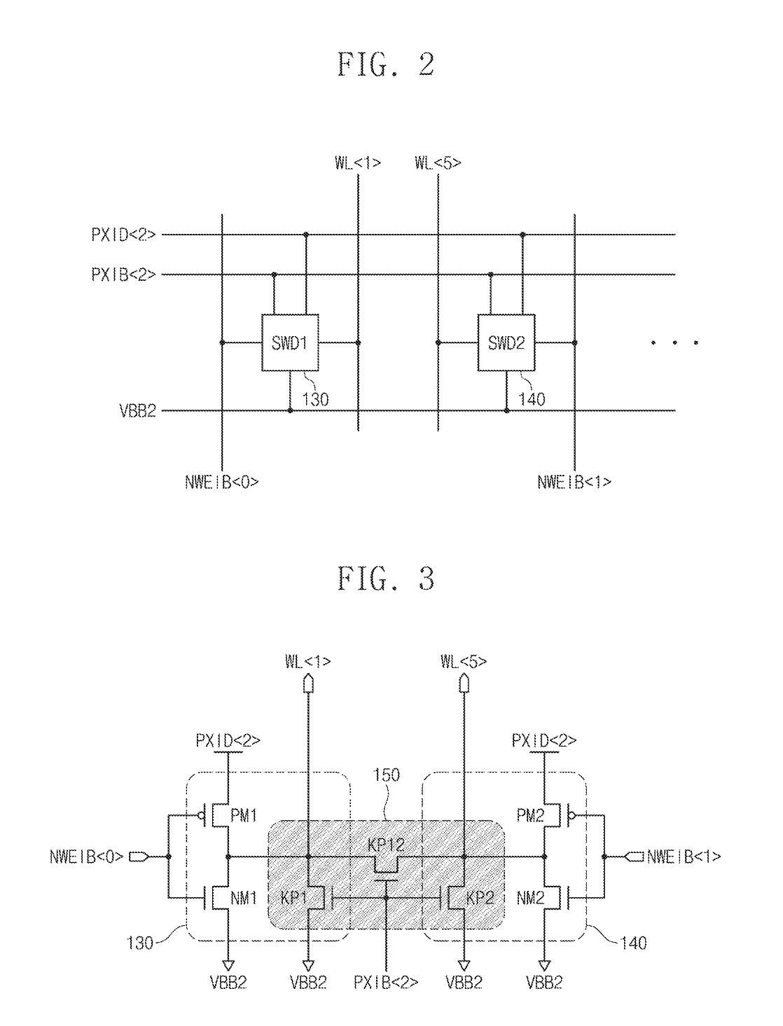

FIG. 2 is a block diagram illustrating adjacent sub-word line drivers according to some embodiments of present inventive concepts. The sub-word line drivers 130 and 140 that drive the word lines WL<1> and WL<5> and are adjacent to each other are illustrated in FIG. 2.

All the sub-word line drivers 130 and 140 may be provided with the driving signals PXID<2> and PXIB<2>. The sub-word line driver 130 may be activated in response to the word line enable signal NWEIB<0>, and the sub-word line driver 140 may be activated in response to the word line enable signal NWEIB<1>. If the word line enable signal NWEIB<0> is activated to a low level “L”, the sub-word line driver 130 provides the word line WL<1> with the high voltage VPP provided through the driving signal PXID<2>. Moreover, if the word line enable signal NWEIB<0> of a high level is provided, the sub-word line driver 130 may block the driving signal PXID<2> and may precharge the word line WL<1>, which may be an inactive word line, with the negative voltage VBB2.

Likewise, if the word line enable signal NWEIB<1> of the low level is provided, the sub-word line driver 140 provides the word line WL<5> with the high voltage VPP provided through the driving signal PXID<2>. If the word line enable signal NWEIB<1> of the high level is provided, the sub-word line driver 140 may block the driving signal PXID<2> and may precharge the word line WL<5> with the negative voltage VBB2.

The sub-word line drivers 130 and 140 include keeping transistors for maintaining the word lines WL<1> and WL<5> at the negative voltage VBB2 after the precharge operation. The keeping transistors may fix/couple the word lines WL<1> and WL<5> to a level of the negative voltage VBB2 in response to the driving signal PXIB<2>. In this case, the word lines WL<1> and WL<5> may maintain a stable voltage value regardless of a level change of the word line enable signals NWEIB<0> and NWEIB<1> or noise (e.g., a noisy signal).

The keeping transistors of the sub-word line drivers 130 and 140 include a common source electrode supplied with the negative voltage VBB2 and a common gate electrode to which the driving signal PXIB<2> is applied. The keeping transistors include two drain electrodes respectively connected with the word lines WL<1> and WL<5>. In a structure where keeping transistors have channels separated from each other, if the cell pitch decreases, channel lengths of the keeping transistors may inevitably decrease. However, in the layout of some embodiments of present inventive concepts, a channel of each keeping transistor is formed in the shape of “Γ”. Accordingly, a channel length may relatively increase, and the resistance to degradation associated with a high voltage may be improved.

FIG. 3 is a circuit diagram illustrating a structure of sub-word line drivers illustrated in FIG. 2. Referring to FIG. 3, the sub-word line drivers 130 and 140 have a circuit structure for driving the word lines WL<1> and WL<5>, respectively. In particular, as gates of keeping (or “keeper”) transistors KP1 and KP2 of the sub-word line drivers 130 and 140 are merged, a parasitic transistor KP12 may be formed between the word lines WL<1> and WL<5>. However, since voltages applied to the word lines WL<1> and WL<5> have almost the same level, a current between a source and a drain of the parasitic transistor KP12 may be negligible/ignorable.

The sub-word line driver 130 may be provided with the driving signals PXID<2> and PXIB<2> from the driving voltage generator 120 (refer to FIG. 1). The sub-word line driver 130 is provided with the word line enable signal NWEIB<0> from the row decoder 110. The sub-word line driver 130 includes a pull-up transistor PM1, a pull-down transistor NM1, and the keeping transistor KP1. The pull-up transistor PM1 pulls the word line WL<1> up to a level of the driving signal PXID<2> in response to the word line enable signal NWEIB<0>. In contrast, the pull-down transistor NM1 pulls the word line WL<1> down to the negative voltage VBB2 in response to the word line enable signal NWEIB<0>. The keeping transistor KP1 allows the word line WL<1> to be maintained at a level of the negative voltage VBB2 at a time point when the word line WL<1> is deactivated. In some embodiments, the keeping transistor KP1 has a source supplied with the negative voltage VBB2 and a drain connected to the word line WL<1> and is turned on or off in response to the driving signal PXIB<2> that is complementary to the driving signal PXID<2>.

The sub-word line driver 140 may be provided with the driving signals PXID<2> and PXIB<2> from the driving voltage generator 120. The sub-word line driver 140 is provided with the word line enable signal NWEIB<1> from the row decoder 110. The sub-word line driver 140 includes a pull-up transistor PM2, a pull-down transistor NM2, and the keeping transistor KP2. The pull-up transistor PM2 pulls the word line WL<5> up to a level of the driving signal PXID<2> in response to the word line enable signal NWEI<1>. In contrast, the pull-down transistor NM2 pulls the word line WL<5> down to the negative voltage VBB2 in response to the word line enable signal NWEI<1>. The keeping transistor KP2 allows the word line WL<5> to be maintained at a level of the negative voltage VBB2 at a time point when the word line WL<5> is deactivated. To this end, the keeping transistor KP2 has a source supplied with the negative voltage VBB2 and a drain connected to the word line WL<5> and is turned on or off in response to the driving signal PXIB<2> that is complementary to the driving signal PXID<2>.

The parasitic transistor KP12 is formed between the keeping transistors KP1 and KP2. That is, the parasitic transistor KP12 that is turned on or off between the word lines WL<1> and WL<5> is formed based on a gate shape of the keeping transistors according to some embodiments of present inventive concepts. However, in the case where the driving signal PXIB<2> is deactivated, the parasitic transistor KP12 is turned off, and thus, the word lines WL<1> and WL<5> are electrically separated. Accordingly, since the word lines WL<1> and WL<5> are maintained at the negative voltage VBB2 only when the sub-word line drivers 130 and 140 are deactivated, the parasitic transistor KP12 does not have an influence on driving the word lines WL<1> and WL<5>.

The keeping transistor KP1 of the sub-word line driver 130 and the keeping transistor KP2 of the sub-word line driver 140 are provided with the same gate voltage corresponding to a voltage of the driving signal PXIB<2>. The same negative voltage VBB2 may be provided to the sources of the keeping transistors KP1 and KP2. According to the layout of some embodiments of present inventive concepts, a channel length of each of the keeping transistors KP1 and KP2 may increase. Accordingly, the resistance to high-voltage stress of the keeping transistors KP1 and KP2 may be improved. Collectively, the keeping transistors KP1, KP2, and KP12 including a parasitic transistor may be referred to herein as a “merged keeping transistor 150”.

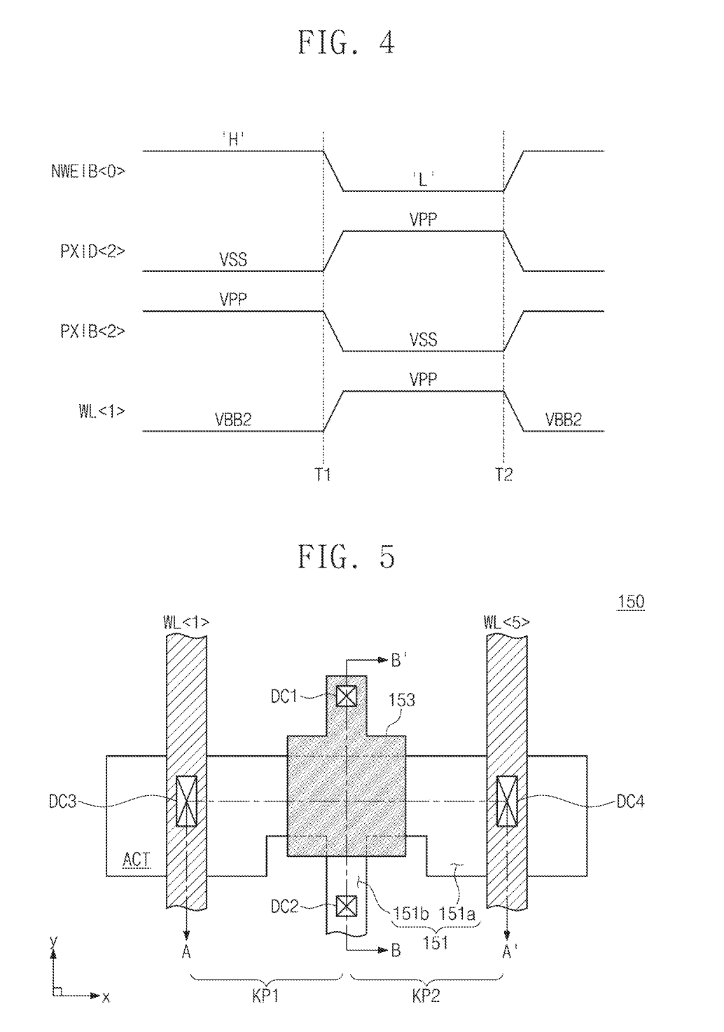

FIG. 4 is a waveform diagram illustrating an operation of a sub-word line driver of FIG. 3. Referring to FIG. 4, the sub-word line driver 130 drives the word line WL<1> with the high voltage VPP or the negative voltage VBB2 in response to the word line enable signal NWEIB<0>.

The sub-word line driver 130 pulls up or pulls down a voltage of the word line WL<1> in response to the word line enable signal NWEIB<0>. It is assumed that the word line enable signal NWEIB<0> is at a high level “H” corresponding to an inactive state before a time point T1. In this case, it is assumed that the driving signal PXID<2> is at the low level “L” and the driving signal PXIB<2> is at the high level “H”. The word line WL<1> may be maintained at the negative voltage VBB2 while the word line enable signal NWEIB<0> is in an inactive state.

At the time point T2, the word line enable signal NWEIB<0> is activated to the low level. Also, the driving signal PXID<2> may transition to a level of the high voltage VPP, and the driving signal PXIB<2> may transition to the low level (e.g., VSS). As the word line enable signal NWEIB<0> transitions to the low level, the pull-up transistor PM1 is turned on, and the pull-down transistor NM1 is turned off. Also, as the driving signal PXIB<2> is maintained at the low level, the keeping transistor KP1 is turned off. In this case, the word line WL<1> and the source of the keeping transistor KP1 are electrically separated. The word line WL<1> and the source of the pull-up transistor PM1 are connected. As such, the driving signal PXID<2> is supplied to the word line WL<1>. Preferably, the driving signal PXID<2> may have a level of the high voltage VPP. A voltage of the word line WL<1> may increase to the level of the high voltage VPP through a pull-up operation of the pull-up transistor PM1.

At a time point T2, the word line enable signal NWEIB<0> is deactivated to the high level. In addition, the driving signal PXID<2> may transition to a ground (VSS) level, and the driving signal PXIB<2> may transition to the high level. As the word line enable signal NWEIB<0> transitions to the high level, the pull-up transistor PM1 is turned off, and the pull-down transistor NM1 is turned on. The keeping transistor KP1 is turned on according to the transition of the driving signal PXIB<2> to the high level. In this case, the word line WL<1> and the source of the keeping transistor KP1 are electrically connected, and the word line WL<1> and the source of the pull-up transistor PM1 are electrically separated. As such, a voltage of the word line WL<1> may decrease to a level of the negative voltage VBB2 by the pull-down transistor NM1 and the keeping transistor KP1.

FIG. 5 is a view illustrating a layout of a merged keeping transistor of FIG. 3. A layout for forming the merged keeping transistor 150 having an extended channel length of adjacent sub-word line drivers SWD1 and SWD2 is illustrated in FIG. 5.

First, an active pattern 151 may be formed in a substrate. A channel and a drain of each of the keeping transistors KP1 and KP2 are formed in the active pattern 151. A common source of the keeping transistors KP1 and KP2 may be formed in the active pattern 151. The common source may be formed at a portion of the active pattern 151 at which the active pattern 151 and a direct contact DC2 are connected. The negative voltage VBB2 may be provided to the common source through the direct contact DC2. In addition, as a channel area connecting the two word lines WL<1> and WL<5> is formed between direct contacts DC3 and DC4, the parasitic transistor KP12 may be formed.

A left area of the merged keeping transistor 150 in which the active pattern 151 is connected with the word line WL<1> through the direct contact DC3 forms the channel and drain of a first keeping transistor KP1. The first keeping transistor KP1 is the keeping transistor KP1 of the sub-word line driver 130 (refer to FIG. 3). A right area of the merged keeping transistor 150 in which the active pattern 151 is connected with the word line WL<5> through the direct contact DC4 forms the channel and drain of a second keeping transistor KP2. The second keeping transistor KP2 is the keeping transistor KP2 of the sub-word line driver 140 (refer to FIG. 3). The common source (or “common source region”) of the first and second keeping transistors KP1 and KP2 is non-collinear with the drain (or “drain region”) of the first keeping transistor KP1 and the drain (or “drain region”) of the second keeping transistor KP2. Accordingly, an axis that extends through the respective drains of the first and second keeping transistors KP1 and KP2 does not extend through the common source. Moreover, the direct contact DC2 may be non-collinear with the direct contacts DC3 and DC4.

The active pattern 151 may be formed as substantially one continuous area, but may be divided into two portions. That is, the active pattern 151 includes a first active pattern 151a extending in an “x” direction that is a direction intersecting the word lines WL<1> and WL<5>. In addition, the active pattern 151 includes a second active pattern 151bthat protrudes in/toward a “y” direction for connection with the direct contact DC2 for forming the common source electrode of the keeping transistors KP1 and KP2. A portion of the active pattern 151 from which the second active pattern 151bstarts to protrude in the “y” direction, that is, a point where the first active pattern 151a and the second active pattern 151b meet, may be any point between the direct contacts DC3 and DC4. The keeping transistors KP1 and KP2 may jointly/collectively comprise (e.g., may share) the first active pattern 151a and the second active pattern 151b. For example, the keeping transistors KP1 and KP2 may include respective portions of the first active pattern 151a, and may include respective portions, or a common portion, of the second active pattern 151b.

A gate pattern 153 of the merged keeping transistor 150 is formed on the active pattern 151. The gate pattern 153 may be formed in the shape of a square as illustrated in FIG. 5. It may be well understood that a gate insulating layer may be formed between the active pattern 151 and the gate pattern 153. The driving signal PXIB<2> may be provided to the gate pattern 153 by using the direct contact DC1. A structural characteristic of the gate pattern 153 is as follows. The gate pattern 153 of present inventive concepts may be provided such that the two keeping transistors KP1 and KP2 share one channel. That is, the gate pattern 153 of present inventive concepts may allow the two keeping transistors KP1 and KP2 to have one common channel. This may mean that channels of the two keeping transistors KP1 and KP2 are not formed independently.

If the high voltage VPP is applied to the gate pattern 153 and the negative voltage VBB2 is provided to the direct contact DC2, the keeping transistors KP1 and KP2 may be turned on. In some embodiments, a T-shaped channel is formed under the gate pattern 153. A channel of the first keeping transistor KP1, which provides an electrical connection with the word line WL<1>, is formed under the gate pattern 153 in a mirrored (i.e., mirror image) “F” shape. Also, a channel of the second keeping transistor KP2, which provides an electrical connection with the word line WL<5>, is formed under the gate pattern 153 in the shape of “F”. As a result, the T-shaped channel area may be formed in the active pattern 151 placed under the gate pattern 153. That is, each of the first keeping transistor KP1 and the second keeping transistor KP2 may have a channel that has a length of “L1” and is formed in the “x” direction and a channel that has a length of “L2” and is formed in the “y” direction.

As the gate pattern 153 of the above-described shape is formed, a channel length of each of the keeping transistors KP1 and KP2 may increase. That is, compared with a structure in which each of the keeping transistors KP1 and KP2 has an independent channel, a channel provided by the merged keeping transistor 150 of present inventive concepts is formed in a bent shape such as the shape of “F”. Accordingly, a channel length of each of the keeping transistors KP1 and KP2 may increase, thereby improving the resistance to degradation of the keeping transistors KP1 and KP2.

The merged keeping transistor 150 of present inventive concepts may have the following characteristics. First, a portion, which forms a common source, of the active pattern 151 for forming the merged keeping transistor 150 protrudes and extends in a downward direction of a “y” axis. Second, the gate pattern 153 of the merged keeping transistor 150 is provided on the active pattern 151 in a convex polygon shape so as to cover both two drains and one common source. For example, the gate pattern 153 may be provided in a square, circle, or ellipse shape. According to the structure of the gate pattern 153, channels of keeping transistors driving different word lines (e.g., WL<1> and WL<5>) are implemented with a single, common (e.g., “merged”) channel (e.g., in the shape of “T”) under the gate pattern 153.

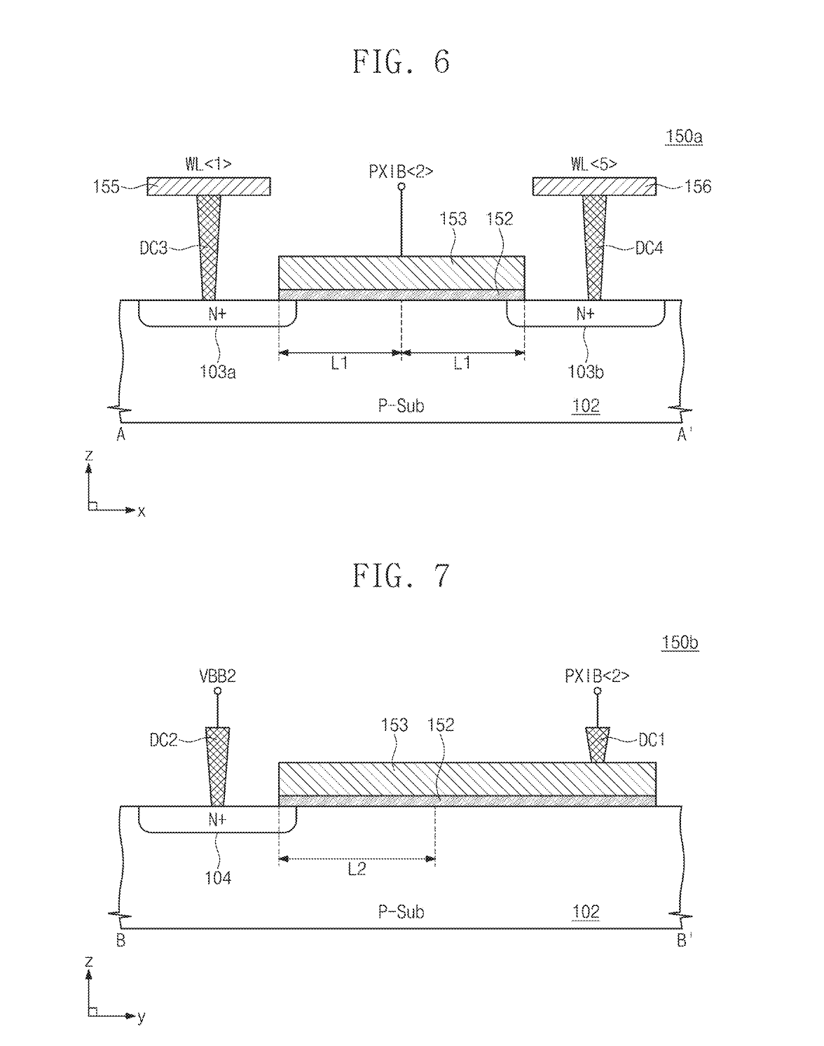

FIG. 6 is a sectional view of a merged keeping transistor taken along a line A-A′ of FIG. 5. A P-type substrate 102 for forming the merged keeping transistor 150, the gate pattern 153, and the word lines WL<1> and WL<5>are illustrated in FIG. 6.

Referring to the cross section 150a of the merged keeping transistor 150, the P-type substrate (P-Sub) 102 for forming NMOS transistors is provided. N+ doping areas 103a and 103b that act as drains of the keeping transistors KP1 and KP2 are formed in the P-type substrate 102. A gate insulating layer 152 and the gate pattern 153 acting as the common gate electrode of the keeping transistors KP1 and KP2 are sequentially stacked on the resultant structure.

The direct contact DC3 for connecting the word line WL<1> and the N+ doping area 103a may be formed on the N+ doping area 103a. The direct contact DC4 for connecting the word line WL<5> and the N+ doping area 103b may be formed on the N+ doping area 103b. Channel lengths in the “x” direction of the keeping transistors KP1 and KP2, respectively, may be “L1” as illustrated in FIG. 5.

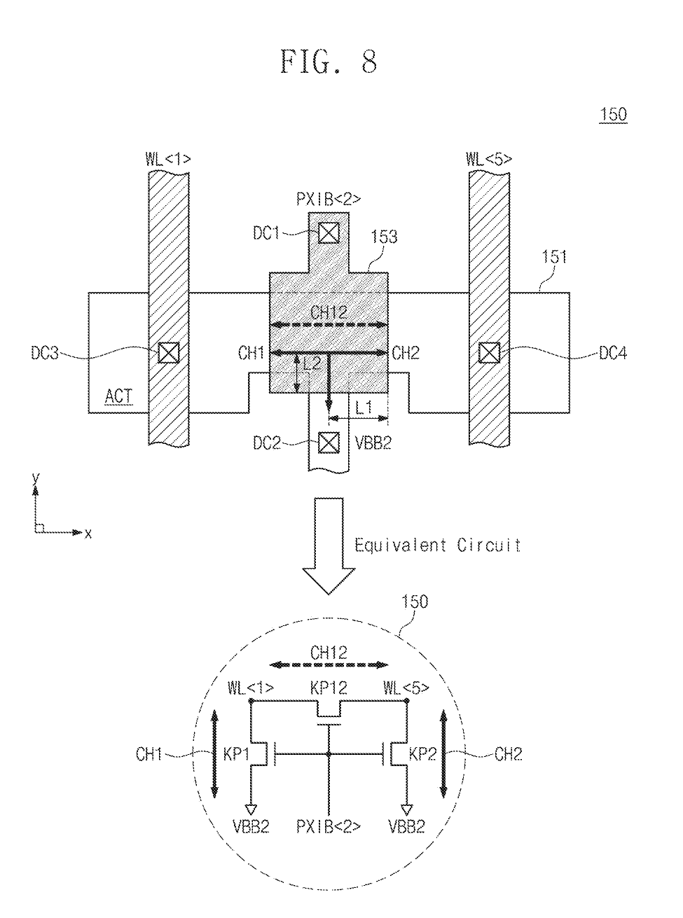

FIG. 7 is a sectional view of a merged keeping transistor taken along a line B-B′ of FIG. 5. The P-type substrate 102 for forming the merged keeping transistor 150, the direct contacts DC1 and DC2, and the gate pattern 153 are illustrated in FIG. 7.

Referring to the cross section 150b of the merged keeping transistor 150, the P-type substrate (P-Sub) 102 for forming NMOS transistors is provided. An N+ doping area 104 that acts as a common source of the keeping transistors KP1 and KP2 is formed in the P-type substrate 102. The gate insulating layer 152 and the gate pattern 153 acting as the common gate electrode of the keeping transistors KP1 and KP2 are sequentially stacked on the resultant structure. In addition, the direct contact DC1 for providing the driving signal PXIB<2> to a gate electrode may be formed on the gate pattern 153. Also, the direct contact DC2 for providing the negative voltage VBB2 to the common source of the merged keeping transistor 150 may be formed in the N+ doping area 104.

In the above-described structure, if the negative voltage VBB2 is provided to the source of the merged keeping transistor 150 through the direct contact DC2, a reverse bias is formed between the N+ doping area 104 and the P-type substrate 102. In this case, a source-drain leakage current of the keeping transistors KP1 and KP2 having the N+ doping area 104 as a source may be inhibited/blocked.

In particular, in the above-described structure, if the high voltage VPP is applied to the gate pattern 153, a channel of the “y” direction is formed in the N+ doping area 104 and an active area under the gate pattern 153. That is, a common channel having a length of “L2” is formed under the gate pattern 153, thus providing an electrical connection with the common source of the keeping transistors KP1 and KP2.

In the above-described structure of the gate pattern 153, a channel length of each of the keeping transistors KP1 and KP2 modeled is “L1+L2”. That is, according to the structure of the merged keeping transistor 150, the first keeping transistor KP1 has a channel length “L1+L2” corresponding to a sum of a channel length “L1” in the “x” direction and a channel length “L2” in the “y” direction. Also, the second keeping transistor KP2 that is formed to be symmetrical (e.g., mirror symmetrical) to the first keeping transistor KP1 has the channel length “L1+L2” corresponding to a sum of the channel length “L1” in the “x” direction and the channel length “L2” in the “y” direction. As a result, the resistance to degradation of the keeping transistors KP1 and KP2 associated with a high voltage may be improved due to the channel length additionally provided in the “y” direction.

FIG. 8 is a view schematically illustrating a channel shape of a keeping transistor according to some embodiments of present inventive concepts. Referring to FIG. 8, a channel length of the merged keeping transistor 150 formed under the gate pattern 153 may be extended in the “y” direction.

A channel CH1 of the first keeping transistor KP1 may be formed under the gate pattern 153 in both the “x” direction and the “y” direction. That is, the channel CH1 may be composed of a channel portion in the “x” direction having the length “L1” and a channel portion in the “y” direction having the length “L2”. In addition, a channel CH2 of the second keeping transistor KP2 may be formed under the gate pattern 153 in both the “x” direction and the “y” direction. That is, the channel CH2 may be composed of a channel portion in the “x” direction having the length “L1” and a channel portion in the “y” direction having the length “L2”.

In addition, a channel CH12 of the parasitic transistor KP12 formed between the two word lines WL<1> and WL<5> is formed. However, a voltage between opposite ends of the parasitic transistor KP12, which are respectively connected to word lines, may be substantially identical in an equivalent circuit of the merged keeping transistor 150 illustrated in FIG. 8. Accordingly, the channel CH12 of the parasitic transistor KP12 may be formed, but a current flowing through the channel CH12 of the parasitic transistor KP12 may be negligible/ignorable.

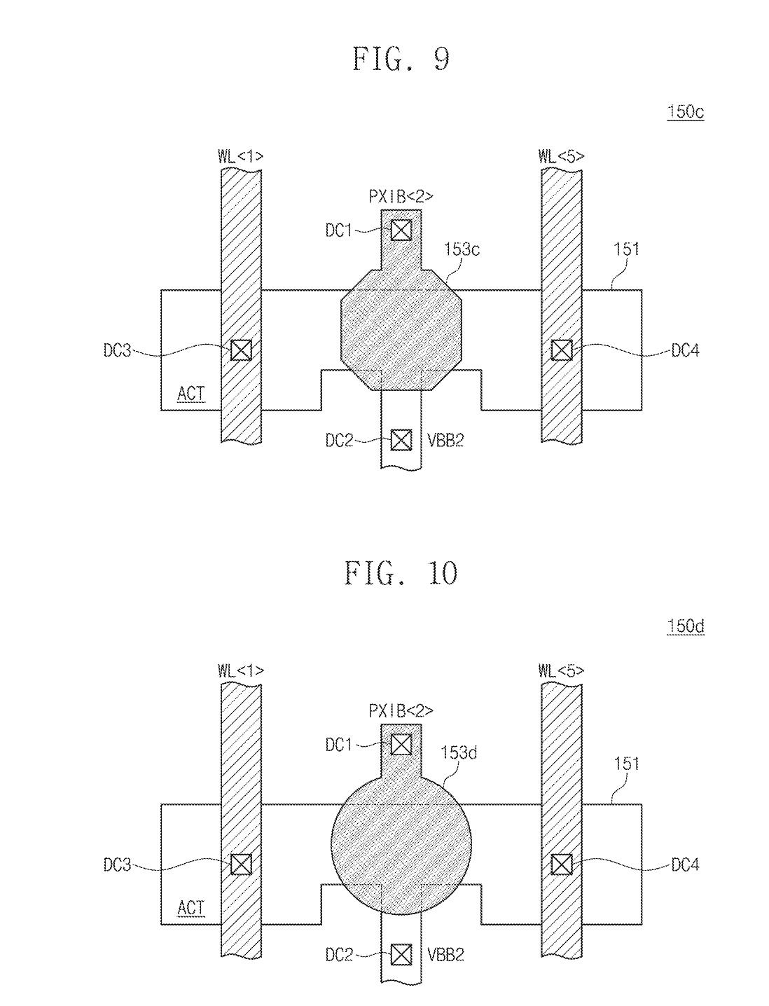

FIG. 9 illustrates a layout of an example of a merged keeping transistor according to some embodiments of present inventive concepts. A gate pattern 153c of a merged keeping transistor 150c may be formed in the shape of an octagon.

A shape of the gate pattern 153c of the merged keeping transistor 150c illustrated in FIG. 9 may be variously changed according to various conditions for implementing the sub-word line driver SWD. In particular, it may be well understood that a shape of the gate pattern may be implemented in various shapes of polygons in consideration of a distance (or cell pitch) between the word lines WL<1> and WL<5> and the arrangement/relationship between the word lines WL<1> and WL<5> and a main word line. For example, the gate pattern 153c may be formed in the shape of a regular octagon in which segments have the same length or may be formed in the shape of an octagon in which lengths of neighboring segments are different from each other.

FIG. 10 illustrates a layout of an example of a merged keeping transistor according to some embodiments of present inventive concepts. A gate pattern 153d of a merged keeping transistor 150d may be formed in the shape of a circle.

A shape of the gate pattern 153d of the merged keeping transistor 150d illustrated in FIG. 10 may be variously changed according to various conditions for implementing the sub-word line driver SWD. In particular, it may be well understood that a shape of the gate pattern 153d may be implemented in various shapes of arcs and/or polygons in consideration of a distance (or cell pitch) between the word lines WL<1> and WL<5> and the (arrangement) relationship between the word lines WL<1> and WL<5> and a main word line. For example, the gate pattern 153d may be formed in the shape of a circle or may be formed in the shape of an ellipse in which a radius in a specific direction is relatively long.

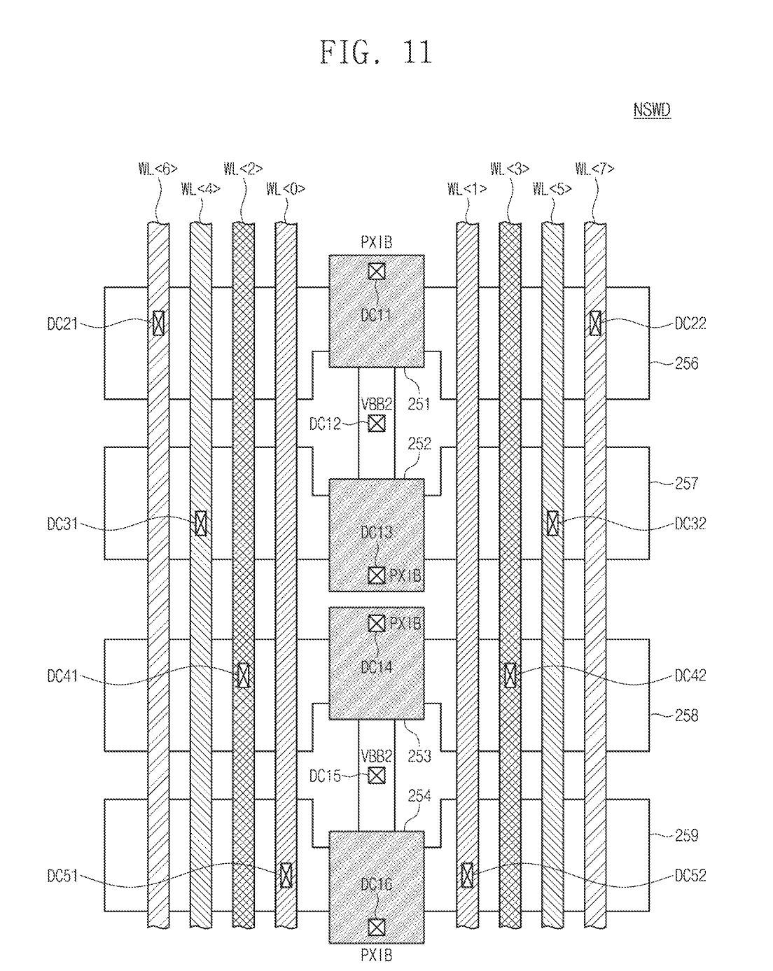

FIG. 11 illustrates an example layout of keeping transistor stages constituting a sub-word line driver of present inventive concepts. Referring to FIG. 11, a plurality of keeping transistors are formed in an NSWD area where NMOS transistors of a sub-word line driver SWD are formed.

First, active patterns 256, 257, 258, and 259 may be formed in a substrate for the purpose of forming keeping transistors for providing the negative voltage VBB2 to word lines WL<1> to WL<7>. Each of the active patterns 256, 257, 258, and 259 includes an active pattern protruding in a direction, in which a word line extends, for the purpose of a common source of two keeping transistors that are merged.

A gate pattern 251 may be formed on the active pattern 256 in the shape of a quadrangle that may be a type of convex polygon. The gate pattern 251 may be driven by a driving signal PXIB provided through a direct contact DC11. A left drain area of the active pattern 256 is connected with the word line WL<6> through a direct contact DC21. A right drain area of the active pattern 256 is connected with the word line WL<7> through a direct contact DC22. The negative voltage VBB2 may be applied through the direct contact DC12 to the active area that protrudes to form a common source. Two keeping transistors may be formed according to the above-described layout, but one channel may be formed under the gate pattern 251.

A gate pattern 252 may be formed on the active pattern 257 in the shape of a quadrangle that may be a type of convex polygon. The gate pattern 252 may be driven by the driving signal PXIB provided through a direct contact DC13. A left drain area of the active pattern 257 is connected with the word line WL<4> through a direct contact DC31. A right drain area of the active pattern 257 is connected with the word line WL<5> through a direct contact DC32. The negative voltage VBB2 may be applied through the direct contact DC12 to the active area that protrudes upwardly to form a common source. Two keeping transistors may be formed according to the above-described layout, but one channel may be formed under the gate pattern 252.

The active patterns 258 and 259 and gate patterns 253 and 254 formed thereon are identical to the active patterns 256 and 257 and the gate patterns 251 and 252 formed thereon except for word lines connected thereto, and thus, a description thereof will not be repeated here. For example, the direct contacts DC14, DC15, DC16, DC41, DC42, DC51, and DC52 may be structured and used identically/similarly to the direct contacts DC11, DC12, DC13, DC21, DC22, DC31, and DC32, respectively.

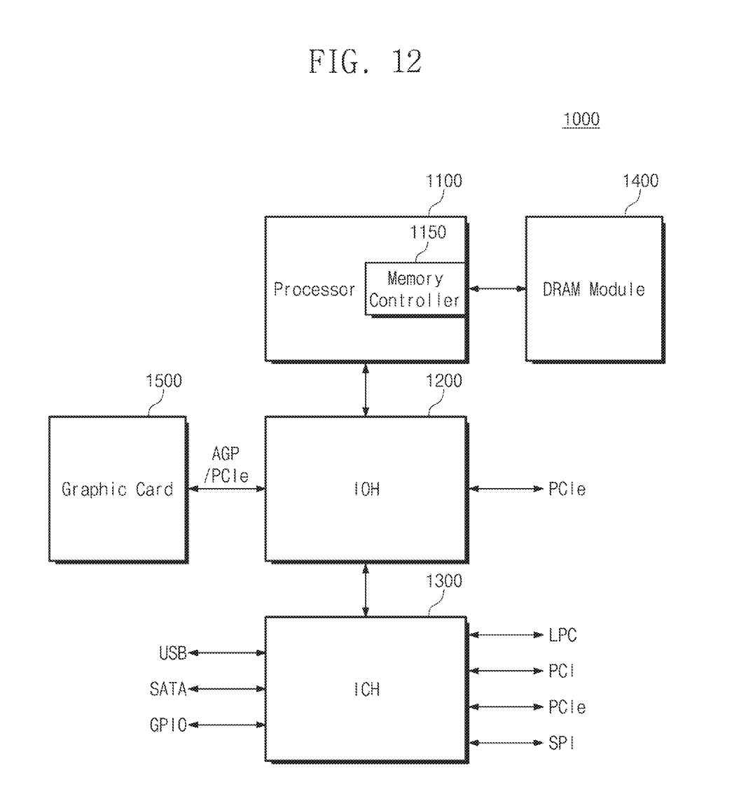

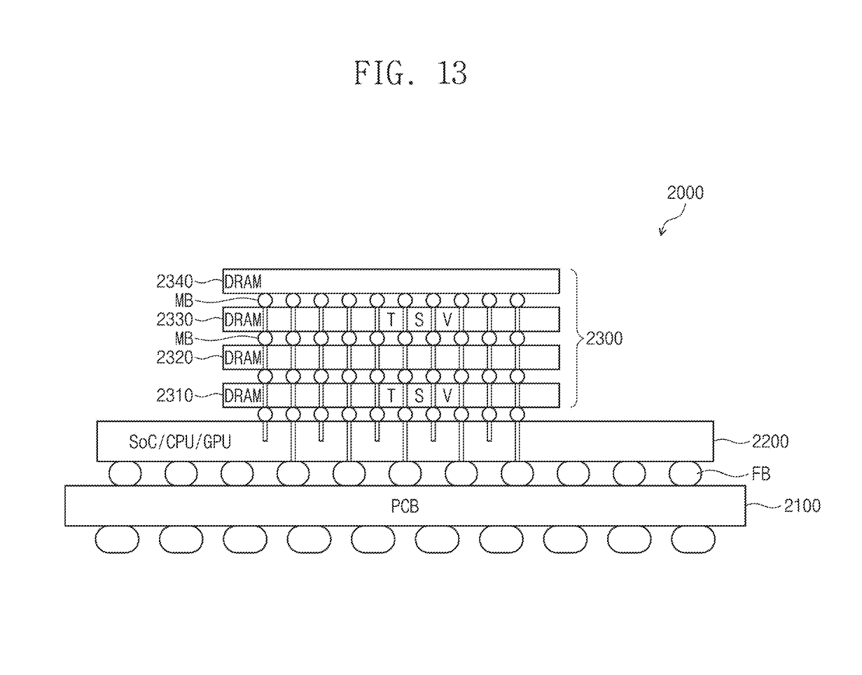

FIG. 12 is a block diagram illustrating a computing system including a semiconductor memory device according to some embodiments of present inventive concepts. Referring to FIG. 12, a computing system 1000 includes a processor 1100, an input/output hub (IOH) 1200, an input/output controller hub (ICH) 1300, at least one DRAM module 1400, and a graphic (or “graphics”) card 1500. Here, the computing system 1000 may be any one of a personal computer (PC), a server computer, a workstation, a laptop, a mobile phone, a smartphone, personal digital assistant (PDA), a portable multimedia player (PMP), a digital camera, a digital television (TV), a set-top box, a music player, a portable game console, and a navigation system.

The processor 1100 may execute various computing functions such as specific calculations or tasks. For example, the processor 1100 may be a microprocessor or a central processing unit (CPU). The processor 1100 may include a single processor core or may include a plurality of processor cores (or a multi-core). For example, the processor 1100 may include a multi-core such as a dual-core, a quad-core, a hexa-core, or the like. Also, the computing system 1000 including one processor 1100 is illustrated in FIG. 12, but the computing system 1000 may include a plurality of processors. Also, the processor 1100 may further include a cache memory that is placed inside or outside the processor 1100.

The processor 1100 may include a memory controller 1150 that controls an operation of the DRAM module 1400. The memory controller 1150 included in the processor 1100 may be called an “integrated circuit memory controller (IMC)”. A memory interface between the memory controller 1150 and the DRAM module 1400 may be implemented with one channel including a plurality of signal lines or with a plurality of channels. Also, one or more DRAM modules may be connected with each channel. The memory controller 1150 may be placed within the input/output hub 1200. The input/output hub 1200 including the memory controller 1150 may be called a “memory controller hub (MCH)”.

The DRAM module 1400 may include a plurality of DRAM devices that store data provided from the memory controller 1150. Each of the DRAM devices may be implemented with the DRAM 100 of FIG. 1. That is, even though a cell pitch is shrunk (e.g., is relatively small), each of the DRAM devices may include a keeping transistor that has high resistance to degradation.

The input/output hub 1200 may manage data transmission between the processor 1100 and devices such as the graphic card 1500. The input/output hub 1200 may be connected to the processor 1100 through interfaces of various types/manners. For example, the input/output hub 1200 and the processor 1100 may be connected through various standards of interfaces such as a front side bus (FSB), a system bus, hypertransport, lightning data transport (LDT), quickpath interconnect (QPI), a common system interface (CSI), and the like. The computing system 1000 including one input/output hub 1200 is illustrated in FIG. 12, but the computing system 1000 may include a plurality of input/output hubs.

The input/output hub 1200 may provide various interfaces with devices. For example, the input/output hub 1200 may provide an accelerated graphics port (AGP) interface, peripheral component interface-express (PCIe), a communications streaming architecture (CSA) interface, and the like.

The graphic card 1500 may be connected with the input/output hub 1200 through AGP or PCIe. The graphic card 1500 may control a display device for displaying an image. The graphic card 1500 may include an internal processor for processing image data and an internal semiconductor memory device. According to some embodiments, the input/output hub 1200 may include the graphic card 1500 placed outside the input/output hub 1200 or may include an integrated graphic device/card instead of separately using the graphic card 1500. The graphic device included in the input/output hub 1200 may be called “integrated graphics”. Also, the input/output hub 1200 including a memory controller and a graphic device may be called a “graphics and memory controller hub (GMCH)”.

The input/output controller hub 1300 may perform data buffering and interface arbitration to allow various system interfaces to operate efficiently. The input/output controller hub 1300 may be connected with the input/output hub 1200 through an internal bus. For example, the input/output hub 1200 and the input/output controller hub 1300 may be connected through a direct media interface (DMI), a hub interface, an enterprise southbridge interface (ESI), PCIe, and the like.

The input/output controller hub 1300 may provide various interfaces with peripheral devices. For example, the input/output controller hub 1300 may provide a universal serial bus (USB) port, a serial advanced technology attachment (SATA) port, a general purpose input/output (GPIO), a low pin count (LPC) bus, a serial peripheral interface (SPI), PCI, PCIe, and the like.

According to some embodiments, the processor 1100, the input/output hub 1200, and the input/output controller hub 1300 may be implemented with separate chipsets or integrated circuits, or two or more of the processor 1100, the input/output hub 1200, and the input/output controller hub 1300 may be implemented with one chipset.

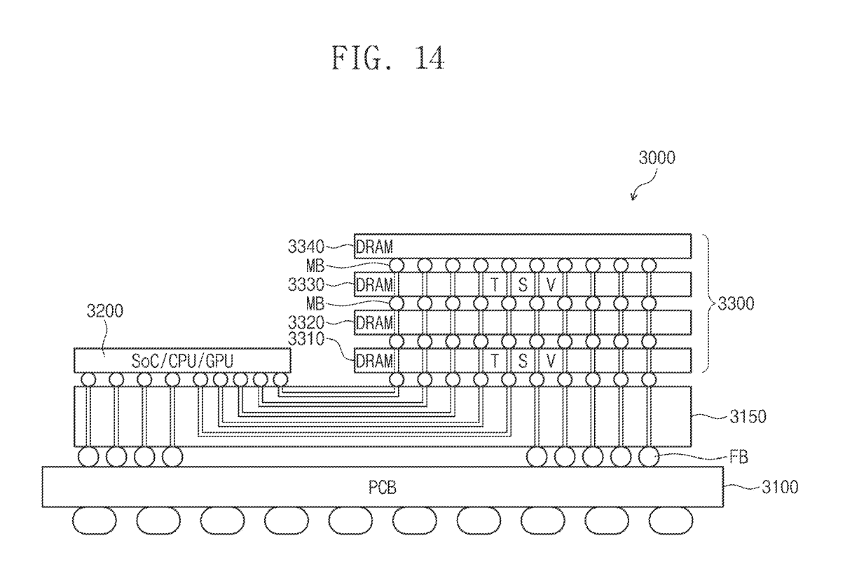

FIG. 13 is a block diagram illustrating a structure of a three-dimensionally stacked memory chip including a DRAM according to some embodiments of present inventive concepts. Referring to FIG. 13, a three-dimensionally stacked memory chip 2000 may include a printed circuit board (PCB) 2100, a host die 2200, and a high bandwidth memory (HBM) 2300.

The host die 2200 such as SoC, CPU, or GPU is disposed on/connected to the PCB 2100 through flip chip bumps FB. A plurality of DRAM dies 2310 to 2340 for constituting the HBM 2300 may be stacked on the host die 2200. A buffer die or any other logic die may be further included on, under, or between the plurality of DRAM dies 2310 to 2340. To implement the structure of the HBM 2300, through silicon via (TSV) lines may be formed in the plurality of DRAM dies 2310 to 2340. The TSV lines may be electrically connected with micro-bumps MB formed between the plurality of DRAM dies 2310 to 2340. Here, the plurality of DRAM dies 2310 to 2340 may be implemented with/as the DRAM 100 of FIG. 1. That is, since each of the plurality of DRAM dies 2310 to 2340 includes a keeping transistor that has high resistance to degradation even though a cell pitch is shrunk (e.g., is relatively small), the plurality of DRAM dies 2310 to 2340 may be highly integrated with high integrity of data.

It is possible to implement the three-dimensionally stacked memory chip 2000 including the HBM 2300 having high integration and high integrity of data.

FIG. 14 is a block diagram illustrating a structure of a stacked memory chip including a DRAM according to some embodiments of present inventive concepts. Referring to FIG. 14, a stacked memory chip 3000 may include a PCB 3100, a TSV interposer layer 3150, a host die 3200, and a HBM 3300.

The stacked memory chip 3000 connects the HBM 3300 and the host die 3200 by using the TSV interposer layer 3150. The TSV interposer layer 3150 is disposed on the PCB 3100 and is electrically connected with the PCB 3100 through flip chip bumps FB.

The host die 3200 and DRAM dies 3310 to 3340 for constituting the HBM 3300 are disposed on the interposer layer 3150. In FIG. 14, a buffer die or a logic die of FIG. 13 may be omitted. However, the buffer die or the logic die may be interposed between the DRAM die 3310 and the TSV interposer layer 3150. To implement the structure of the HBM 3300, through silicon via (TSV) lines are formed in the plurality of DRAM dies 3310 to 3340. The TSV lines may be electrically connected with micro-bumps MB formed between the plurality of DRAM dies 3310 to 3340.

Here, the plurality of the plurality of DRAM dies 3310 to 3340 may be implemented with/as the DRAM 100 of FIG. 1. That is, since each of the plurality of DRAM dies 3310 to 3340 includes a keeping transistor that has high resistance to degradation even though a cell pitch is shrunk (e.g., is relatively small), the plurality of DRAM dies 3310 to 3340 may be highly integrated with high integrity of data.

According to some embodiments of present inventive concepts, it may be possible to provide a sub-word line driver having an increased channel length even though a distance between word lines is reduced. Accordingly, it may be possible to provide a semiconductor memory device having high reliability in addition to improvement of integration.

Although present inventive concepts have been described with reference to example embodiments thereof, it will be apparent to those of ordinary skill in the art that various changes and modifications may be made thereto without departing from the spirit and scope of present inventive concepts as set forth in the following claims.

What is claimed is:

1. A semiconductor memory device comprising:
a first sub-word line driver comprising a first keeper transistor that is configured to supply a negative voltage to a first word line in response to a driving signal; and
a second sub-word line driver comprising a second keeper transistor that is configured to supply the negative voltage to a second word line in response to the driving signal,
wherein the first keeper transistor and the second keeper transistor jointly comprise:
a first active pattern extending in a first direction intersecting the first word line and the second word line and connected with the first word line and the second word line through a first direct contact and a second direct contact, respectively;
a second active pattern protruding from the first active pattern in a second direction intersecting the first direction and connected with a third direct contact that is configured to supply the negative voltage; and
a gate pattern on a portion of the first active pattern.

2. The semiconductor memory device of claim 1, wherein a single channel of the first keeper transistor and the second keeper transistor is between the first direct contact, the second direct contact, and the third direct contact.

3. The semiconductor memory device of claim 2, wherein the single channel comprises a “T” shape.

4. The semiconductor memory device of claim 1,
wherein the first keeper transistor comprises a first NMOS transistor, and
wherein the second keeper transistor comprises a second NMOS transistor.

5. The semiconductor memory device of claim 1, wherein the first sub-word line driver further comprises:
a first pull-up transistor configured to pull the first word line up to a higher voltage than the negative voltage in response to a first word line enable signal; and
a first pull-down transistor configured to pull the first word line down to the negative voltage in response to the first word line enable signal.

6. The semiconductor memory device of claim 5, wherein the second sub-word line driver further comprises:
a second pull-up transistor configured to pull the second word line up to the higher voltage in response to a second word line enable signal; and
a second pull-down transistor configured to pull the second word line down to the negative voltage in response to the second word line enable signal.

7. The semiconductor memory device of claim 1,
wherein the first sub-word line driver and the second sub-word line driver are adjacent each other, and
wherein the semiconductor memory device further comprises a parasitic transistor that is between the first sub-word line driver and the second sub-word line driver, and that is connected to the first word line and the second word line.

8. The semiconductor memory device of claim 1, further comprising a fourth direct contact that is on the gate pattern and that is configured to provide the driving signal to the gate pattern, wherein the gate pattern is in contact with the second active pattern and comprises a shape of a convex polygon, an ellipse, or a circle.

9. A sub-word line driver of a semiconductor memory device, the sub-word line driver comprising:
a substrate comprising a first drain region and a second drain region of a plurality of keeper transistors, and a common source region of the plurality of keeper transistors, wherein the plurality of keeper transistors is configured to couple a plurality of inactive word lines to a negative voltage; and
a common gate electrode of the plurality of keeper transistors,
wherein the common source region of the plurality of keeper transistors is non-collinear with the first drain region and the second drain region of the plurality of keeper transistors.

10. The sub-word line driver of claim 9, wherein the first drain region, the common source region, and the common gate electrode provide a first keeper transistor, of the plurality of keeper transistors, that is configured to precharge a first word line, of the plurality of inactive word lines, with the negative voltage.

11. The sub-word line driver of claim 10, further comprising a first direct contact that is configured to connect the first drain region and the first word line, and that is on the first drain region.

12. The sub-word line driver of claim 11, wherein the second drain region, the common source region, and the common gate electrode provide a second keeper transistor, of the plurality of keeper transistors, that is configured to precharge a second word line, of the plurality of inactive word lines, with the negative voltage.

13. The sub-word line driver of claim 12, further comprising a second direct contact that is configured to connect the second drain region and the second word line, and that is on the second drain region.

14. The sub-word line driver of claim 9, further comprising a common channel of the plurality of keeper transistors that is under the common gate electrode and between the first drain region, the second drain region, and the common source region.

15. The sub-word line driver of claim 9, further comprising a parasitic transistor that comprises a source and a drain that are respectively connected with the first drain region and the second drain region.

16. A semiconductor memory device comprising:
a first keeper transistor that is connected to a first word line, and that is configured to supply a voltage to the first word line in response to a driving signal; and
a second keeper transistor that is connected to a second word line, and that is configured to supply the voltage to the second word line in response to the driving signal,
wherein the first keeper transistor and the second keeper transistor comprise a merged channel.

17. The semiconductor memory device of claim 16, further comprising a gate electrode that is shared by the first keeper transistor and the second keeper transistor.

18. The semiconductor memory device of claim 17, wherein the gate electrode comprises at least one of a convex polygon shape, a circle shape, or an ellipse shape.

19. The semiconductor memory device of claim 16, wherein the merged channel comprises a “T” shape.

20. The semiconductor memory device of claim 19, wherein the first keeper transistor and the second keeper transistor comprise a first NMOS keeper transistor of a first sub-word line driver and a second NMOS keeper transistor of a second sub-word line driver, respectively.
